(19) United States
(12) Patent Application Publication
(10) Pub. No.: US 2023/0185527 A1
(43) Pub. Date: Jun. 15, 2023

(54) METHOD AND APPARATUS WITH DATA COMPRESSION

(71) Applicant: SAMSUNG ELECTRONICS CO., LTD., Suwon-si (KR)

(72) Inventors: Hyesun HONG, Seoul (KR); SEUNGWON LEE, Hwaseong-si (KR)

(73) Assignee: SAMSUNG ELECTRONICS CO., LTD., Suwon-si (KR)

(21) Appl. No.: 17/862,500

(22) Filed: Jul. 12, 2022

(30) Foreign Application Priority Data
Dec. 9, 2021 (KR) 10-2021-0175748

(51) Int. Cl. G06F 7/485

(52) U.S. Cl. CPC G06F 7/485

(57) ABSTRACT

An electronic device that compresses data and an operating method thereof are provided. The electronic device includes a processor configured to express each of a plurality of data according to a floating-point format that includes a sign field, an exponent identifier field, and a mantissa field, wherein an exponent identifier field included in each of the plurality of data includes a bit value that represents any one of a plurality of exponents.

### CROSS-REFERENCE TO RELATED APPLICATIONS

This application claims the benefit under 35 USC § 119(a) of Korean Patent Application No. 10-2021-0175748, filed on Dec. 9, 2021, in the Korean Intellectual Property Office, the entire disclosure of which is incorporated herein by reference for all purposes.

### BACKGROUND

### 1. Field

The following description relates to a method and apparatus with data compression.

### 2. Description of Related Art

A floating-point may be a format to represent real numbers as an approximation to generally support a wide range of values. A number that is based on the floating-point may be typically represented approximately with a fixed number of significant digits and may be scaled using an exponent. The term floating-point may refer to the fact that a number's radix point (e.g., a decimal point, or a binary point used in a computer) may float. The floating-point may have the exponent and a mantissa, and may be expressed by adjusting the exponent to express the mantissa with significant digits. When expressing the exponent and the mantissa, a normalization operation and a bias operation may be added internally, but a wide range of numbers compared to a number of bits may be expressed, so the floating-point may have an advantage in terms of precision.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, an electronic device includes a processor, configured to execute instructions, and a memory, storing the instructions, which, when executed by the processor, configures the processor to: express each of a plurality of data based on a floating-point format that comprises a sign field, an exponent identifier field, and a mantissa field, wherein the exponent identifier field comprised in each of the plurality of data comprises a respective bit value that represents any one of a plurality of exponents.

The plurality of exponents may be stored in data fields different from data fields of the plurality of data.

A total number of bits of the exponent identifier field may be determined based on a total number of the plurality of exponents.

A total number of bits of the exponent identifier field may be less than or equal to a total number of bits of each of the plurality of exponents.

The processor may be further configured to determine whether an exponential difference between first data and second data on which an operation is set to be performed, by the processor, among the plurality of data is greater than a predetermined threshold, and perform an operation between the first data and the second data using an operation scheme that is determined based on a result of the determining.

The processor is configured to, in response to the exponential difference being less than the predetermined threshold, perform the operation between the first data and the second data by separating an exponent of the first data and an exponent of the second data and a mantissa of the first data and a mantissa of the second data from each other.

The processor is configured to, in response to the exponential difference being greater than the predetermined threshold, accumulate one of the first data and the second data that has a smaller exponent, in an accumulator.

The processor is configured to, in response to an accumulation of values in the accumulator being at a level that affects one or more predetermined bits of one of the first data and the second data that has a greater exponent, perform an operation between a cumulative value of the values accumulated in the accumulator and the one of the first data and the second data that has the greater exponent.

The accumulator may be configured to have an exponent that is greater than the exponent of one of the first data and the second data which has the smaller exponent and less than the exponent of one of the first data or the second data which has the greater exponent.

The processor may be further configured to perform an operation for a bit range determined based on a total number of bits of a mantissa of one of the first data and the second data which has the greater exponent, and a total number of bits of a mantissa in the accumulator; and a total number of bits of a mantissa in an overlapping exponent range between the one of the first data and the second data which has the greater exponent and the accumulator.

The operation between the first data and the second data may include an addition and/or a subtraction of the first data and the second data.

In a general aspect, a processor-implemented operating method includes expressing first data based on a floating-point format that comprises a sign field, an exponent identifier field, and a mantissa field; and expressing second data based on the floating-point format, wherein the exponent identifier field comprised in each of the first data and the second data comprises a respective bit value that represents any one of a plurality of exponents, and wherein the expressing of the first data and the expressing of the second data are performed by a processor configured according to instructions executed by the processor.

The plurality of exponents may be stored in data fields different from data fields storing the first data and the second data.

A total number of bits of the exponent identifier field may be determined based on a total number of the plurality of exponents.

A total number of bits of the exponent identifier field may be less than or equal to a total number of bits of each of the plurality of exponents.

The method may include determining whether an exponential difference between the first data and the second data on which an operation is to be performed among the plurality of data is greater than a predetermined threshold; and performing an operation between the first data and the second data using an operation scheme that is determined based on a result of the determining.

In response to the exponential difference being less than the predetermined threshold, the performing of the operation by the processor comprises performing the operation by separating an exponent of the first data and an exponent of the second data and a mantissa of the first data and a mantissa of the second data from each other.

In response to the exponential difference being greater than the predetermined threshold, the performing of the operation may include accumulating one of the first data and the second data which has a smaller exponent, in an accumulator.

In response to an accumulation of values in the accumulator at a level that affects one or more predetermined bits of one of the first data and the second data which has a greater exponent, the performing of the operation by the processor comprises performing an operation between a cumulative value of the values accumulated in the accumulator and one of the first data and the second data which has the greater exponent.

In a general aspect, a processor implemented method includes determining, by a processor, whether an exponential difference between first data and second data on which an operation is to be performed is greater than a predetermined threshold based on respective exponent identifier fields in the first data and the second data; performing, by a processor separate processes on exponents of the first data and the second data, and mantissas of the first data and the second data, with a block floating point operation based on a determination that the exponential different is less than the predetermined threshold; and performing, by the processor, separate processes on exponents of the first data and the second data, and mantissas of the first data and the second data, with a block floating point operation and a lazy update based on a determination that the exponential different is greater than the predetermined threshold.

The separate processes may be at least one or more of addition processes, subtraction processes, and multiplication processes.

The threshold may be dynamically determined by the processor in an electronic device in a data processing process.

Other features and aspects will be apparent from the following detailed description, the drawings, and the claims.

### BRIEF DESCRIPTION OF DRAWINGS

FIG. 1 illustrates an example electronic device, in accordance with one or more embodiments.

FIG. 2 illustrates an example floating-point format, in accordance with one or more embodiments.

FIG. 3, FIG. 4, FIG. 5, and FIG. 6 illustrate example operations of a floating-point format, in accordance with one or more embodiments.

FIG. 7 and FIG. 8 illustrate example applications with the floating-point format, in accordance with various embodiments.

FIG. 9 illustrates an example method, in accordance with one or more embodiments.

Throughout the drawings and the detailed description, unless otherwise described or provided, the same drawing reference numerals will be understood to refer to the same, or like, elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

The terminology used herein is for the purpose of describing particular examples only, and is not to be used to limit the disclosure. As used herein, the singular forms “a,” “an,” and “the” are intended to include the plural forms as well, unless the context clearly indicates otherwise. As used herein, the term “and/or” includes any one and any combination of any two or more of the associated listed items. As used herein, the terms “include,” “comprise,” and “have” specify the presence of stated features, numbers, operations, elements, components, and/or combinations thereof, but do not preclude the presence or addition of one or more other features, numbers, operations, elements, components, and/or combinations thereof.

In addition, terms such as first, second, A, B, (a), (b), and the like may be used herein to describe components. Each of these terminologies is not used to define an essence, order, or sequence of a corresponding component but used merely to distinguish the corresponding component from other component(s).

Unless otherwise defined, all terms, including technical and scientific terms, used herein have the same meaning as commonly understood by one of ordinary skill in the art to which this disclosure pertains after an understanding of the disclosure of the present application. Terms, such as those defined in commonly used dictionaries, are to be interpreted as having a meaning that is consistent with their meaning in the context of the relevant art and the disclosure of the present application, and are not to be interpreted in an idealized or overly formal sense unless expressly so defined herein.

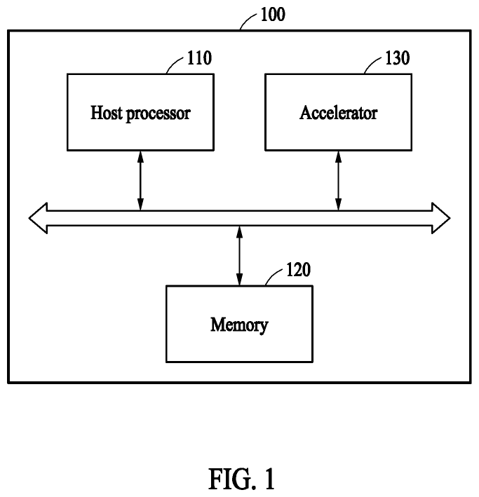

FIG. 1 illustrates an example electronic device, in accordance with one or more embodiments.

Referring to FIG. 1, an electronic device 100 may include a host processor 110, a memory 120, and a hardware accelerator 130. The host processor 110, the memory 120, and the accelerator 130 may communicate with each other through a bus, a network on a chip (NoC), a peripheral component interconnect express (PCI), and the like. The electronic device 100 may also include other general-purpose components, in addition to the components illustrated in FIG. 1, as a non-limiting example.

The host processor 110 may be a single processor or one or more processors configured to control the electronic device 100. The host processor 110 may control the electronic device 100, or components within the electronic device 100, by executing coding and/or instructions stored in the memory 120. The electronic device may perform various data processing, data compression, or other operations as non-limiting examples. In an example, as at least a portion of data processing, data compression, or other operations, the processor may store an instruction or data received from another component in a volatile or non-volatile memory, may process the instruction or the data stored in a volatile or non-volatile memory, and may store result data in a volatile or non-volatile memory. In an example, the processor may include a main processor (e.g., a central processing device and an application processor) or an auxiliary processor (e.g., a graphical processing device, a neural processing unit (NPU), an image signal processor, a sensor hub processor, and a communication processor), e.g., operable independently from or together with the main processor. For example, when the electronic device includes the main processor and the auxiliary processor, the auxiliary processor may be set to use less power than that of the main processor or may be configured to specialize in a specified function. The auxiliary processor may be implemented separate from or as a portion of the main processor. For example, the host processor 110 may be implemented as a central processing unit (CPU), a graphics processing unit (GPU), an application processor (AP), and the like, that are included in the electronic device 100, but examples of which are not limited thereto. Herein, it is noted that use of the term ‘may’ with respect to an example or embodiment, e.g., as to what an example or embodiment may include or implement, means that at least one example or embodiment exists where such a feature is included or implemented while all examples and embodiments are not limited thereto.

The memory 120 may be hardware to store data processed in the electronic device 100 and data to be processed. Additionally, the memory 120 may store an application, a driver, and the like to be driven by the electronic device 100. The memory 120 may include a volatile memory (e.g., dynamic random-access memory (DRAM)) and/or a nonvolatile memory.

The electronic device 100 may include a hardware accelerator 130 that performs one or more determined operations. The hardware accelerator 130 may process tasks that may be more efficiently processed by a separate exclusive processor (that is, the hardware accelerator 130), rather than by the general-purpose host processor 110, due to characteristics of the tasks. In an example, one or more processing elements (PEs) included in the hardware accelerator 130 may be utilized. The hardware accelerator 130 may correspond to, as non-limiting examples, a neural processing unit (NPU), a tensor processing unit (TPU), a digital signal processor (DSP), a GPU, a neural engine, and the like that perform operation(s) according to a neural network or other machine learning models.

The processor described below may be implemented as the hardware accelerator 130. However, the examples are not limited thereto, and the processor may be implemented as the host processor 110.

Data processed by the processor may be expressed in a floating-point format. A floating-point is a scheme of expressing a real number as an approximation, and may be expressed with a mantissa indicating a valid number without fixing a position of a decimal point and an exponent indicating the position of the decimal point. For example, a 64-bit floating-point format may include a 1-bit sign field, a 52-bit mantissa field, and an 11-bit exponent field. The term “floating-point” may refer to the fact that a number's decimal point may “float” or be placed anywhere within a number relevant to the significant digits in the number. The position of the decimal point is based on an exponent, which modifies the magnitude of the number. To derive the value of the floating-point number, the significand is multiplied by the base raised to the power of the exponent. For example, in the relation “a×2^{b}”, “a” corresponds to a significand or mantissa, “2” corresponds to the base, and “b” corresponds to an exponent.

In an example, when expressing data in the floating-point format, rather than using a result of converting the data to a binary number as the mantissa, the processor may normalize the result of converting the data to a binary number and convert the result to a 1. ###×2ⁿ form, and then express a part after the decimal point (that is, a ### part) as the mantissa. Since a left part of the decimal point is always 1, the left part is not expressed in the floating-point and may be called a hidden bit. A bias value according to total bits of the floating-point may be added to an exponent n obtained by normalization, and then the sum may be converted to a binary number. In an example, a bias value for the 64-bit floating-point format may be 1023.

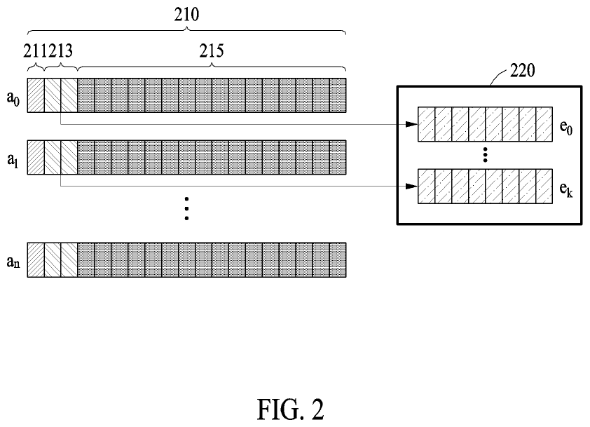

Depending on an application that utilizes data expressed according to the floating-point format, data may share some exponents. In this application, some exponents shared by the data may be stored in separate data fields, the data may include identification information indicating any one of the shared exponents instead of directly including exponents to reduce a number of bits that represent the exponents so that an amount of the data may be reduced, or may utilize the number of bits reduced in the exponents to represent a mantissa so that a range of numbers that may be expressed may increase. Additionally, since a number of bits expressing the shared exponents may be sufficiently used in the separate data fields, a loss may not occur even in an exponent range that determines precision. This will be described in detail with reference to FIG. 2.

FIG. 2 illustrates an example floating-point format, in accordance with one or more embodiments.

Referring to FIG. 2, each of a plurality of data 210 may include a sign field 211, an exponent identifier field 213, and a mantissa field 215. A plurality of exponents 220 may be stored in data fields different from data fields of the plurality of data 210. Examples of a number of bits of each field are illustrated in FIG. 2. However, the examples are not limited thereto, and various numbers of bits may be adopted.

The sign field 211 may include 1 bit that represents a sign of data. In an example, the sign field 211 may include a value of “0” when the data is a positive number and include a value of “1” when the data is a negative number.

The exponent identifier field 213 may include a bit value that represents any one of the plurality of exponents 220. The plurality of exponents 220 may include a predetermined number (e.g., k) of exponents that are shared by the plurality of data 210. In an example, the plurality of exponents 220 may be k exponents predetermined according to a data application, but examples are not limited thereto, and may be dynamically added, deleted, or replaced by an electronic device in a data processing process.

When the number of the plurality of exponents 220 is 8, a number of bits of the exponent identifier field 213 may be determined to be log₂ k. In an example, when the number of the plurality of exponents 220 is 4, the number of bits of the exponent identifier field 213 may be determined to be 2. When the exponent identifier field 213 includes a “00” bit, the corresponding exponent identifier field 213 may represent a first exponent e₀, and when the exponent identifier field 213 includes an “11” bit, the corresponding exponent identifier field 213 may represent a last exponent e₃.

The number of bits of the exponent identifier field 213 may be less than or equal to the number of bits of each of the plurality of exponents 220, so that the data may express an exponent having a large bit with a small number of bits, and accordingly, more bits may be utilized when expressing a mantissa.

The mantissa field 215 may include bits that represent a mantissa of the data. Expressing a mantissa that determines a range of numbers that may be expressed with a small number of bits may improve a data compression rate.

The data 210 may share the plurality of exponents 220 and include the exponent identifier field 213 that represents any one of the plurality of exponents 220, so that the data may be effectively expressed through the exponent identifier field 213 even if a range of the data 210 varies.

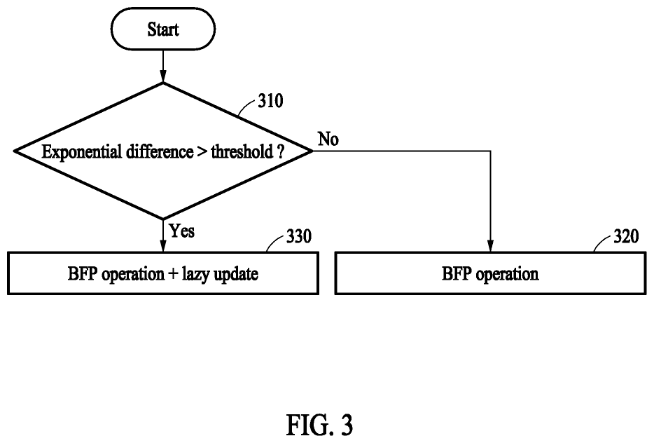

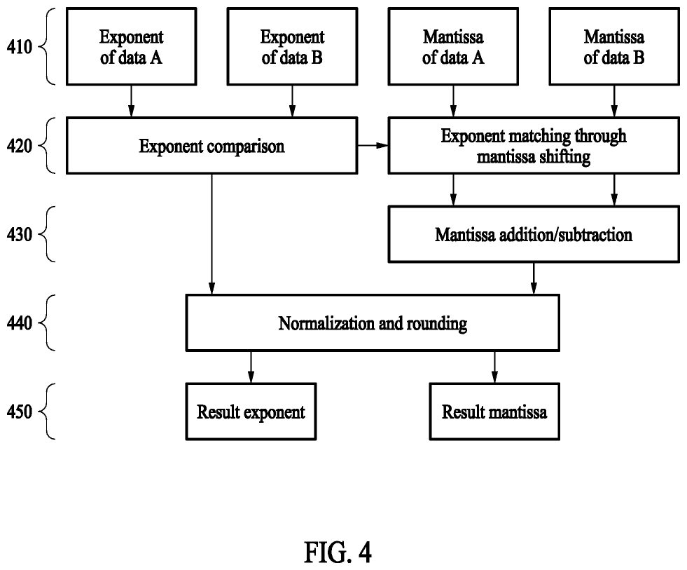

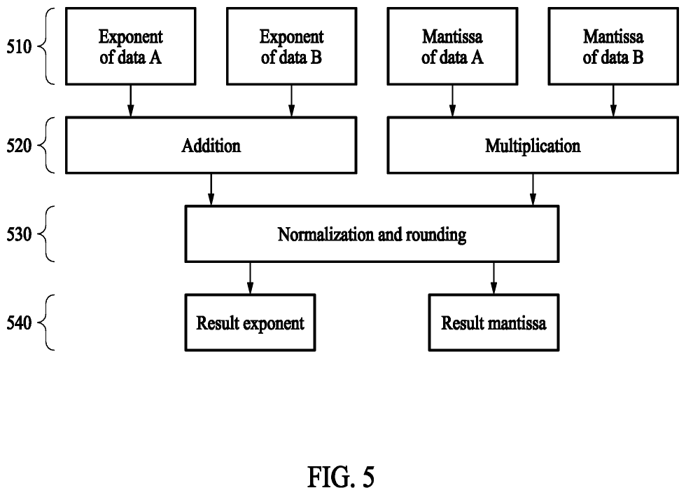

FIGS. 3 to 6 illustrate example operations of a floating-point format, in accordance with various embodiments.

Referring to FIG. 3, an example of operating data expressed in the previously described floating-point format is illustrated. The operations in FIG. 3 may be performed in the sequence and manner as shown. However, the order of some operations may be changed, or some of the operations may be omitted, without departing from the spirit and scope of the shown example. Additionally, operations illustrated in FIG. 3 may be performed in parallel or simultaneously. One or more blocks of FIG. 3, and combinations of the blocks, can be implemented by special purpose hardware-based computer that perform the specified functions, or combinations of special purpose hardware and instructions, e.g., computer or processor instructions. In addition to the description of FIG. 3 below, the descriptions of FIGS. 1-2 are also applicable to FIG. 3, and are incorporated herein by reference. Thus, the above description may not be repeated here for brevity purposes. The operations of FIG. 3 may be performed by a processor of an electronic device.

In operation 310, the processor, for example, host processor 110, may determine whether an exponential difference between data (for example, first data and second data) on which an operation is to be performed is greater than a predetermined threshold. The processor may determine the exponential difference of the data by checking exponents for the respective data based on respective exponent identifier field values included in the data. The threshold may be predetermined according to an application. However, the examples are not limited thereto, and the threshold may be dynamically determined by the electronic device in a data processing process.

When the exponential difference between the data is not greater than the threshold, operation 320 may be performed subsequently, or when the exponential difference is greater than the threshold, operation 330 may be performed subsequently. When the exponential difference is equal to the threshold, any one of operations 320 and 330 may be performed subsequently according to a predetermined setting.

In operation 320, the processor may perform an operation between the data, (for example, first data and second data), based on a block floating-point (BFP) operation. The processor may perform separate operations on the exponents and mantissas of the data.

As the BFP is a floating-point format that assigns exponents to all data instead of assigning exponents to individual data, so that the BFP may have advantages of a fixed point and a floating-point. The BFP may increase a range of numbers in which the data may be expressed more than a fixed point by sharing some exponents of the data, and may be more economical than a general floating-point by separating a common exponent. The BFP operation will be described with reference to FIGS. 4 and 5.

Referring to FIG. 4, an example of adding or subtracting data based on a BFP operation is illustrated, in accordance with one or more embodiments.

In operation 410, a processor may separate exponents of data A and data B on which an operation is to be performed and mantissas of the data A and the data B from each other. In operation 420, the processor may compare the exponent of the data A and the exponent of the data B. The processor may shift at least one of the mantissas of the data A and the data B based on a comparison result of the exponents to match the exponents of the data A and the data B. In operation 430, the processor may perform addition operations or subtraction operations on the mantissas of the data A and the data B with the exponents in a matched state. In operation 440, the processor may apply the previously matched exponent to a result of the addition operation or the subtraction operation of the mantissas, and then perform normalization and rounding that are performed in a process of conversion to a floating-point format on the result. In operation 450, the processor may obtain an exponent and a mantissa of the operation result through the normalization and the rounding.

Referring to FIG. 5, an example of multiplying data based on a BFP operation is illustrated, in accordance with one or more embodiments.

In operation 510, a processor may separate exponents of data A and data B on which an operation is to be performed and mantissas of the data A and the data B from each other. In operation 520, the processor may add the exponents of the data A and the data B and multiply the mantissas of the data A and the data B. Since an exponential difference between the data A and the data B is less than a threshold, the previously described operations may be performed on the exponents of the data A and the data B and the mantissas of the data A and the data B. In operation 530, the processor may perform normalization and rounding, which are performed in a process of conversion to a floating-point format, for operation results of the exponents and the mantissas. In operation 540, the processor may obtain an exponent and a mantissa resulting from the operations through the normalization and the rounding.

Referring again to FIG. 3, in operation 330, which is performed when the exponential difference between the data is greater than the threshold, the processor may perform addition operations or subtraction operations between the data based on a BFP operation to which a lazy update is applied. Even when the exponential difference between the data is greater than the threshold, the multiplication between the data may be performed in a same manner as described in FIG. 5. The addition operation or the subtraction operation between the data based on the BFP operation to which the lazy update is applied will be described in detail with reference to FIG. 6.

Referring to FIG. 6, an example of performing data addition and data subtraction to which a lazy update is applied is illustrated. A number of bits of each field shown in FIG. 6 is illustrated. However, the one or more examples are not limited thereto, and various numbers of bits may be adopted.

When an exponential difference between data is greater than a threshold, an operation of data having a smaller exponent may be ignored. In an example, in training a neural network, when a gradient value is too small, it may be difficult to apply the gradient value to a parameter value of the neural network. An accumulator 630 may be implemented so that the operation of the data having the smaller exponent may not be ignored. In one or more examples, for ease of description, among data, data having a greater exponent may be referred to as data A 610, and data having a smaller exponent may be referred to as data B 620.

Mantissa fields of the data A 610, the data B 620, and the accumulator 630 in FIG. 6 may include bits of which sizes may be expressed according to the horizontal axis. In an example, in FIG. 6, an illustration showing that the last two bits of the mantissa field of the data A 610 and the first two bits of the mantissa field in the accumulator 630 overlap on the horizontal axis may indicate that sizes of the corresponding bits are the same. In other words, a last bit of the mantissa field of the data A 610 and a second bit of the mantissa field in the accumulator 630 may be disposed on the same horizontal axis, indicating that sizes of the two bits are same.

Horizontal axis positions of the data A 610, the data B 620, and the accumulator 630 may be determined based on an exponent of each data. The data A 610 having a greater exponent may be disposed on a left side of the data B 620 having a smaller exponent. The accumulator 630 may have an exponent that is a median size of the exponent size of the data A 610 and the exponent size of the data B 620 in order to prevent the data B 620 from being ignored in an operation process, and thus the accumulator 630 may be disposed between the data A 610 and the data B 620 on the horizontal axis.

For the data A 610, the data B 620, and the accumulator 630, a sign field may only represent a sign of each data, and an exponent identifier field may only represent an exponent of each data, and thus these fields may be irrelevant to a size according to the horizontal axis.

In the example of FIG. 6, the bits in the mantissa field of the data A 610 may not overlap the bits in the mantissa field of the data B 620 on the horizontal axis, and accordingly, the data B 620 may be ignored in a process of adding the data A 610 and the data B 620. As a number of ignored data increases, an error of an operation result may increase. To prevent this, the data B 620 may be accumulated in the accumulator 630 in performing the addition operation. As the operation is performed multiple times, a cumulative value in the accumulator 630 may increase. When the accumulator 630 has values accumulated enough to affect the data A 610, some of the values in the accumulator 630 may be added to the data A 610. In an example, an 0 bit illustrated in FIG. 6 may represent a number of bits of a mantissa in an overlapping exponent range between the accumulator 630 and the data A 610. When the values accumulated in the accumulator 630 appear in the O bit, the O bit may be added to the data A 610, and a value corresponding to the O bit may be deleted from the accumulator 630. In an example, the O bit may represent the number of bits of a mantissa in the overlapping exponent range between the data A 610 and the accumulator 630.

A result of an addition between data having a large exponential difference may not appear immediately, but small exponent values may be accumulated to be reflected later, which may be referred to as a lazy update, and accordingly, an addition error for the data having the large exponential difference may be minimized.

Although the foregoing description is based on an addition operation for ease of description, the description may apply to subtraction operations as well, and thus a more detailed description will be omitted.

In an example, data addition or data subtraction to which the lazy update is applied may be performed in a range of M+N−2−O−2 log₂ k bits. M may be a total number of bits of the data A 610, N may be a total number of bits of the data B 620, O may represent the aforementioned O bit, 2 log₂ k may represent a sum of a number of bits of the exponent identifier field of the data A 610 and a number of bits of the exponent identifier field of the data B 620, and 2 may represent a sum of a number of bits of the sign field of the data A 610 and a number of bits of the sign field of the data B 620. Specifically, the data addition operation or the subtraction operation to which the lazy update is applied may be performed in a bit range determined based on a number of bits of a mantissa of the data A 610 and a number of bits of a mantissa of the data B 620, and the number of bits of the mantissa in the overlapping exponent range between the data A 610 and the accumulator 630.

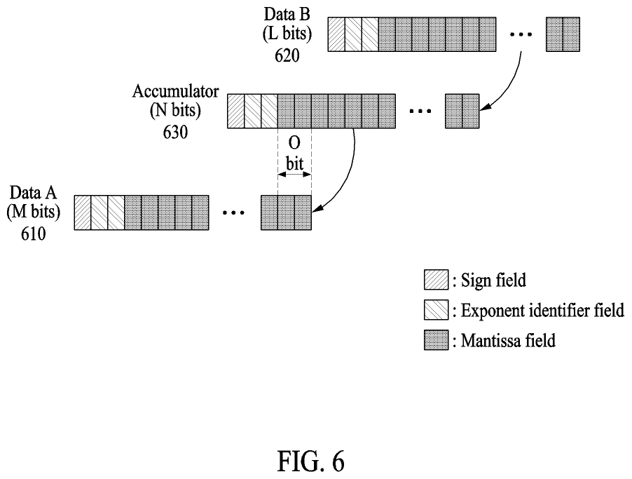

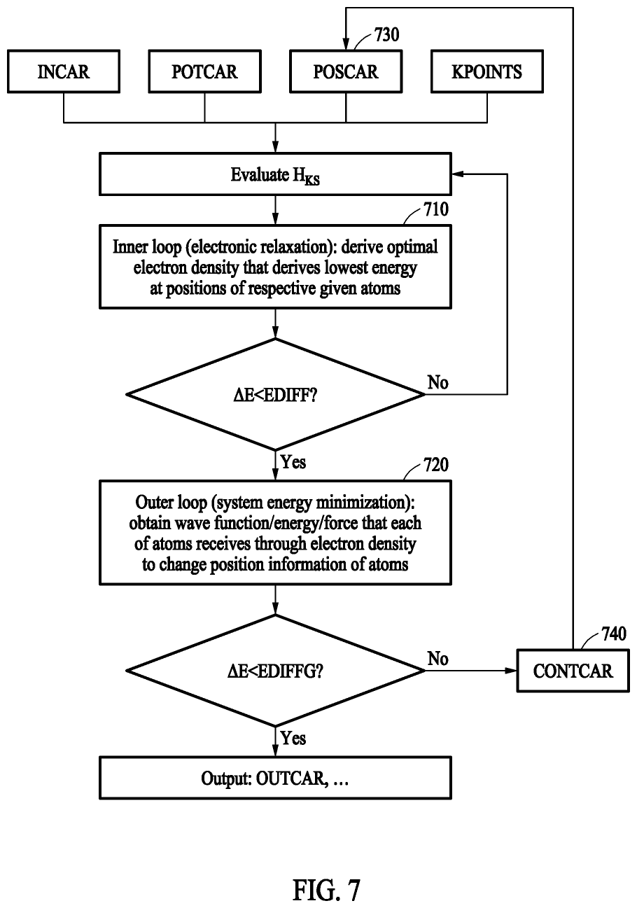

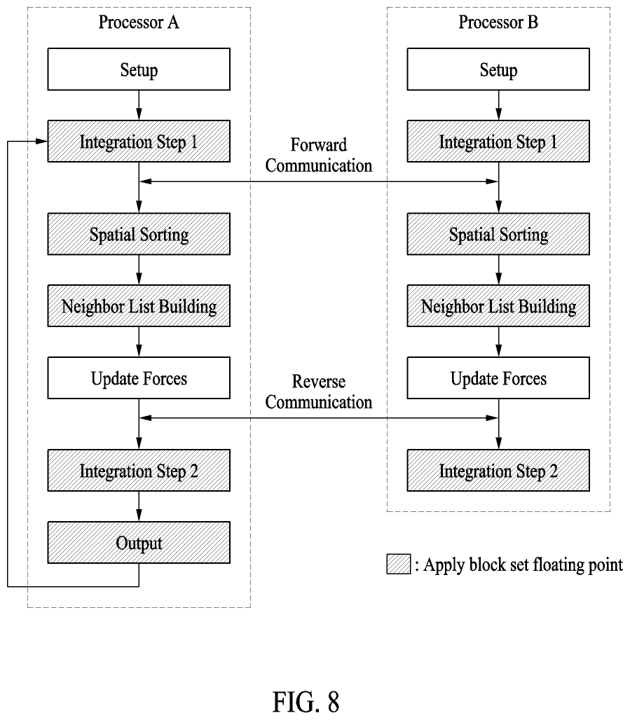

In FIG. 6, although an example with one accumulator 630 is illustrated, this is only an example, and in one or more examples, a plurality of accumulators 630 may be provided depending on an application. In a molecular dynamics (MD) application and a density functional theory (DFT) application to be described in FIGS. 7 and 8, a position of an atom may be determined separately for an x-axis, a y-axis, and a z-axis, and a first accumulator for an operation to be performed on the x-axis, a second accumulator for an operation to be performed on the y-axis, and a third accumulator for an operation to be performed on the z-axis may be implemented. Since the foregoing description may apply to the implementation of the accumulators for the operations to be performed on the respective x-axis, y-axis, and z-axis, a more detailed description will be omitted.

For ease of description, the previously described floating-point format that includes a sign field, an exponent identifier field, and a mantissa field may be referred to as a block set floating-point format.

FIGS. 7 and 8 illustrate examples of applications to which a floating-point format is applied.

An MD workload and a DFT workload are tasks that determine a characteristic of a material by implementing a movement of an atom or an electron, and operation accuracy for an electron density or a position and/or velocity of the atom may be important. In an example, a large-scale atomic/molecular massively parallel simulator (LAMMPS), which may be used for the MD workload, may calculate static and dynamic characteristics of an interatomic potential based on the position and velocity of the atom. Additionally, a Vienna ab initio simulation package (VASP) used in the DFT workload may search for a most stable arrangement and structure of the atom using the electron density and the position of the atom. For the two workloads, it may be important to reflect position and velocity values of the atom, which vary slightly in every iteration, with high accuracy, and here, the previously described block set floating-point format may be utilized.

Referring to FIG. 7, an example of utilizing the previously described block set floating-point format in the VASP is illustrated, in accordance with one or more embodiments.

In a quantum mechanics calculation, it may be possible to predict a behavior of an electron, which is a basis of a material, to find out characteristics of all materials and phenomena thereof. The VASP may be based on the DFT. The VASP may calculate characteristics related to ground-state energy (e.g., total energy, barrier energy, band structure, density of states, phonon spectra, etc.) of a system and phenomena thereof with electronic relaxation and ionic relaxation. The calculation in the VASP may be performed in a way of finding the ground-state energy of the system while the electronic relaxation and the ionic relaxation are repeated as shown in FIG. 7.

In the VASP, the electronic relaxation process and the ionic relaxation process may be repeated until the system finds the ground-state energy, or may be repeated a particular number of times. The electronic relaxation process (i.e., an inner loop) 710 may be a process of finding an optimal electron density that derives a lowest energy at positions of given atoms. A system energy minimization process (i.e., an outer loop) 720 may obtain a wave function, energy values, and a force that each of the atoms receives through the electron density to change position information of the atoms. The electronic relaxation process 710 and the system energy minimization process 720 may be repeated until most stable atomic arrangement and atomic structure are obtained. In an example, the positions and velocities of the atoms may change slightly, rather than significantly, in every iteration.

The previously described block set floating-point format may apply to POSCAR 730 and CONTCAR 740. The INCAR file may be the central input file of VASP. The POTCAR file contains the pseudopotential for each atomic species used in the calculation. The POSCAR file may contain the lattice geometry and the ionic positions, optionally also starting velocities and predictor-corrector coordinates for a MD-run. After each ionic step and at the end of each job a CONTCAR file may be written.

The POSCAR 730 and CONTCAR 740 may be related to position data and velocity data of the atoms. In an example, a variation in the position/velocity of the atom may be expressed as ten or less exponents, and data may include an exponent identifier field value indicating any one of the corresponding exponents. Alternatively, the variation in the position/velocity of the atom may be reflected immediately or may be reflected to an accumulator based on a lazy update, according to an exponential difference of data on which an operation is to be performed.

Referring to FIG. 8, an example of utilizing the previously described block set floating-point format in a LAMMPS is illustrated.

MD may calculate, in a system having N atoms, an empirical/semi-empirical potential acting between the atoms and then solve Newton's equation of motion to find out evolution of each of the atoms over time, and discover static and dynamic characteristics of the corresponding atoms. In the MD, an operation may be performed on an atom basis, and not an electron basis. The LAMMPS may be included in tools that perform the MD. In an example, in a tersoff application of the LAMMPS, a process of calculating a potential between the atoms using current position information of the atoms, then reflecting positions and velocities of the atoms that change due to a next potential again to the position information of the atoms, and re-calculating the potential between the atoms based on the changed position information may be repeated.

Referring to FIG. 8, an example of the tersoff application of the LAMMPS that is performed separately in two processors is illustrated. Each of the two processors may utilize, in calculating a position and velocity of an atom in a corresponding area, information of a neighboring atom that does not belong to the corresponding area, but may be adjacent thereto. The information of the neighboring atom may be transmitted between the processors through forward communication and reverse communication. In FIG. 8, steps to which the block set floating-point format may be applied may be separately indicated, and in the corresponding steps, when data is expressed based on the previously described block set floating-point format to reduce a number of bits, communication may be performed with a small amount of data so that a communication overhead may be reduced. Additionally, the data may be sorted based on position and velocity values having the same exponents in every iteration, and then an operation may be performed only with mantissa values of the corresponding data, and an operation of changing the exponent values of the data may be performed only when necessary, and thus operations per second (OPS) may be improved.

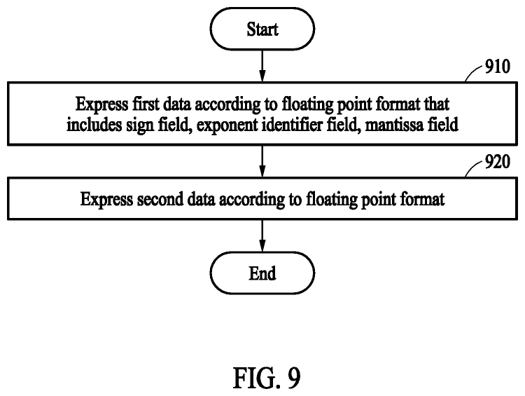

Position, velocity, potential, and energy values of atoms used in the MD workload and the DFT workload described in FIGS. 8 and 9 may have significantly small variations and thus, may be expressed in relative variations as well as absolute variations. If the values have to be transmitted or stored to another node, the values may be expressed with a smaller number of bits so that a communication speed may be improved, and a storage capacity may be reduced. For example, the relative variations may be determined based on a spatial or temporal difference value.

When double precision floating-point applies to the MD workload and the DFT workload, as accuracy may be mainly determined by the mantissa values, and most values have similar exponent values, and thus, the data may be expressed inefficiently. When multiple nodes and accelerators are used for acceleration, an amount of communication between the nodes or accelerators increases, which may lead to a performance bottleneck. By applying the previously described block set floating-point to the MD workload and the DFT workload, it may be possible to effectively overcome a limitation of the double precision floating-point and extend an exponent range that may apply to the data through an exponent identifier field value indicating any one of a plurality of exponents to express a variety of data without limitation.

FIG. 9 illustrates an example operating method of an example electronic device, in accordance with one or more embodiments. The operations in FIG. 9 may be performed in the sequence and manner as shown. However, the order of some operations may be changed, or some of the operations may be omitted, without departing from the spirit and scope of the shown example. Additionally, operations illustrated in FIG. 9 may be performed in parallel or simultaneously. One or more blocks of FIG. 9, and combinations of the blocks, can be implemented by special purpose hardware-based computer that perform the specified functions, or combinations of special purpose hardware and instructions, e.g., computer or processor instructions. In addition to the description of FIG. 3 below, the descriptions of FIGS. 1-8 are also applicable to FIG. 9, and are incorporated herein by reference. Thus, the above description may not be repeated here for brevity purposes. The operations of FIG. 9 may be performed by a processor of the electronic device.

Referring to FIG. 9, in operation 910, the example electronic device may express first data based on a floating-point format that includes a sign field, an exponent identifier field, and a mantissa field. A number of bits of the exponent identifier field may be determined based on a number of a plurality of exponents. The number of bits of the exponent identifier field may be less than, or equal to, a number of bits of each of the plurality of exponents.

In operation 920, the electronic device may express second data based on the floating-point format. An exponent identifier field included in each of the first data and the second data may include a bit value that represents any one of the plurality of exponents. The plurality of exponents may be stored in data fields different from data fields of the first data and the second data.

The electronic device may determine whether an exponential difference between the first data and the second data on which an operation is to be performed among the plurality of data is greater than a predetermined threshold, and perform an operation between the first data and the second data by implementing an operation scheme determined according to a result of the determining. In response to the exponential difference not being greater than the threshold, the electronic device may perform the operation by separating exponents of the first and second data and mantissas of the first and second data from each other. In response to the exponential difference being greater than the threshold, the electronic device may accumulate data having a smaller exponent, in an accumulator, the data being one of the first data and the second data. In response to an accumulation of values in the accumulator at a level that is enough to affect one or more predetermined bits of data having a greater exponent, the data being one of the first data and the second data, the electronic device may perform an operation between a cumulative value that is the values accumulated in the accumulator and the data having the greater exponent.

In an example, the electronic device may be various computing devices (e.g., a mobile phone, a smartphone, a tablet computer, an e-book device, a laptop, a personal computer (PC), and a server), various wearable devices (e.g., a smart watch, smart eyeglasses, a head-mounted display (HMD), and smart clothes), various home appliances (e.g., a smart speaker, a smart television (TV), and a smart refrigerator), and other devices (e.g., a smart vehicle, a smart kiosk, an Internet of things (IoT) device, a walking assistant device (WAD), a drone, and a robot). Additionally, in order to accelerate high performance computing (HPC) software (SW), the electronic device may include a server product group having a plurality of system on a chip (SoCs) including a plurality of cores, a layered memory structure and an interconnect between the cores. Alternatively, the electronic device may perform a block floating-point fast Fourier transform (BFP FFT) algorithm, a digital signal processor (DSP) algorithm in a field-programmable gate array (FPGA), and an artificial intelligence (AI)/machine learning (ML) workload.

In an example, an electronic device may effectively reduce an amount of communication data and/or minimize an amount of data stored when performing checkpoint to drive stably, e.g., for a long period by expressing the data according to the previously described block set floating-point format. Additionally, in an example, a larger number of values may be stored in a cache when a memory is accessed, so that the cache may be used more efficiently. Further, in an example, if all exponents necessary for an application are included in a plurality of shared exponents, data may be processed without mantissa shift.

The host processor 110, accelerator 130, memory 120, and other devices, and other components described herein are implemented as, and by, hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods that perform the operations described in this application, and illustrated in FIGS. 1-11, are performed by computing hardware, for example, by one or more processors or computers, implemented as described above executing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller, e.g., as respective operations of processor implemented methods. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that be performed by the hardware components and the methods as described above. In one example, the instructions or software include machine code that is directly executed by the one or more processors or computers, such as machine code produced by a compiler. In another example, the instructions or software include higher-level code that is executed by the one or more processors or computers using an interpreter. The instructions or software may be written using any programming language based on the block diagrams and the flow charts illustrated in the drawings and the corresponding descriptions in the specification, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), EEPROM, RAM, DRAM, SRAM, flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors and computers so that the one or more processors and computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent to one of ordinary skill in the art, after an understanding of the disclosure of this application, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

What is claimed is:

1. An electronic device, comprising:
a processor, configured to execute instructions, and
a memory, storing the instructions, which, when executed by the processor, configures the processor to:
express each of a plurality of data based on a floating-point format that comprises a sign field, an exponent identifier field, and a mantissa field,
wherein the exponent identifier field comprised in each of the plurality of data comprises a respective bit value that represents any one of a plurality of exponents.

2. The electronic device of claim 1, wherein the plurality of exponents are stored in data fields different from data fields storing the plurality of data.

3. The electronic device of claim 1, wherein a total number of bits of the exponent identifier field is determined based on a total number of the plurality of exponents.

4. The electronic device of claim 1, wherein a total number of bits of the exponent identifier field is less than or equal to a total number of bits of each of the plurality of exponents.

5. The electronic device of claim 1, wherein the processor is further configured to:
determine whether an exponential difference between first data and second data on which an operation is set to be performed, by the processor, among the plurality of data is greater than a predetermined threshold, and
perform an operation between the first data and the second data using an operation scheme that is determined based on a result of the determining.

6. The electronic device of claim 5, wherein, the processor is configured to, in response to the exponential difference being less than the predetermined threshold, perform the operation between the first data and the second data by separating an exponent of the first data and an exponent of the second data and a mantissa of the first data and a mantissa of the second data from each other.

7. The electronic device of claim 5, wherein the processor is configured to, in response to the exponential difference being greater than the predetermined threshold, accumulate one of the first data and the second data that has a smaller exponent, in an accumulator.

8. The electronic device of claim 7, wherein the processor is configured to, in response to an accumulation of values in the accumulator being at a level that affects one or more predetermined bits of one of the first data and the second data that has a greater exponent,
perform an operation between a cumulative value of the values accumulated in the accumulator and the one of the first data and the second data that has the greater exponent.

9. The electronic device of claim 7, wherein the accumulator is configured to have an exponent that is greater than the exponent of one of the first data and the second data that has the smaller exponent and less than the exponent of one of the first data or the second data that has the greater exponent.

10. The electronic device of claim 7, wherein the processor is further configured to perform an operation for a bit range determined based on:
a total number of bits of a mantissa of one of the first data and the second data that has the greater exponent, and a total number of bits of a mantissa in the accumulator; and
a total number of bits of a mantissa in an overlapping exponent range between the one of the first data and the second data that has the greater exponent and the accumulator.

11. The electronic device of claim 7, wherein the operation between the first data and the second data comprises an addition and/or a subtraction of the first data and the second data.

12. A processor-implemented operating method, comprising:
expressing first data based on a floating-point format that comprises a sign field, an exponent identifier field, and a mantissa field; and
expressing second data based on the floating-point format,
wherein the exponent identifier field comprised in each of the first data and the second data comprises a respective bit value that represents any one of a plurality of exponents, and
wherein the expressing of the first data and the expressing of the second data are performed by a processor configured according to instructions executed by the processor.

13. The method of claim 12, wherein the plurality of exponents are stored in data fields different from data fields storing the first data and the second data.

14. The method of claim 12, wherein a total number of bits of the exponent identifier field is determined based on a total number of the plurality of exponents.

15. The method of claim 12, wherein a total number of bits of the exponent identifier field is less than or equal to a total number of bits of each of the plurality of exponents.

16. The method of claim 12, further comprising:
determining whether an exponential difference between the first data and the second data on which an operation is set to be performed, by the processor, among the plurality of data is greater than a predetermined threshold; and
performing an operation between the first data and the second data using an operation scheme that is determined based on a result of the determining.

17. A non-transitory computer-readable storage medium storing instructions that, when executed by a processor, causes the processor to perform the operating method of claim 12.

18. A processor-implemented method, comprising:
determining, by a processor, whether an exponential difference between first data and second data on which an operation set to be performed is greater than a predetermined threshold based on respective exponent identifier fields in the first data and the second data;
performing, by the processor, separate processes on exponents of the first data and the second data, and mantissas of the first data and the second data, with a block floating point operation based on a determination that the exponential difference is less than the predetermined threshold; and
performing, by the processor, separate processes on exponents of the first data and the second data, and mantissas of the first data and the second data, with a block floating point operation and a lazy update based on a determination that the exponential difference is greater than the predetermined threshold.

19. The method of claim 18, wherein the separate processes are at least one or more of addition processes, subtraction processes, and multiplication processes.

20. The method of claim 18, wherein the threshold is dynamically determined by the processor in an electronic device in a data processing process.
